(19) United States
(12) Patent Application Publication
(10) Pub. No.: US 2026/0101431 A1
(43) Pub. Date: Apr. 9, 2026

(54) PRINTED CIRCUIT BOARD ARRANGEMENT

(71) Applicant: Rolls-Royce Deutschland Ltd & Co KG, Blankenfelde-Mahlow (DE)

(72) Inventors: Uwe WALTRICH, Forchheim (DE); Niklas SCHAMBERGER, Nürnberg (DE); Marco BOHLLÄNDER, Hirschaid (DE); Maria BØE, Trondheim (NO)

(21) Appl. No.: 19/350,271

(22) Filed: Oct. 6, 2025

(30) Foreign Application Priority Data
Oct. 7, 2024 (DE) 10 2024 128 812.4

(51) Int. Cl. H05K 1/02

(52) U.S. Cl. CPC H05K 1/021; H05K 1/0277; H05K 2201/066; H05K 2201/10393; H05K 2201/10409; H05K 2201/10522

(57) ABSTRACT

A printed circuit board assembly comprising a printed circuit board having a top side and an underside, electrical modules having a top side and an underside, a heat sink that is thermally coupled with the underside of the electrical modules, and a hold-down device. The heat sink has a structured top side that includes a plurality of cavities and bearing structures arranged between the cavities and forming a bearing surface for the printed circuit board. The underside of the printed circuit board lies on the bearing surface and the region of the underside that is lying on the bearing surface forms a bottom abutment surface, the electrical modules project into the cavities of the heat sink, and the hold-down device has projecting structures against the top side of the printed circuit board at contact points located opposite the bottom abutment surface and apply a hold-down force to the contact points.

This application claims the benefit of the German patent application number DE 10 2024 128 812.4, filed on Oct. 7, 2024, which is hereby incorporated by reference in its entirety.

### TECHNICAL FIELD

The present disclosure relates to a printed circuit board assembly.

### BACKGROUND

For effective cooling, it is known to press printed circuit board-based power electronics assemblies against a heat sink by screw connections. The power electronics assemblies-also referred to as prepackage modules-to be cooled are located on the underside of a printed circuit board. It is desirable to keep the number of screws as small as possible so as not to limit the printed circuit board layout too greatly by the screw connections. Each screw connection thus leads to holes in the printed circuit board, and these holes reduce the available copper cross section. In addition, air gaps and creepage paths are maintained on the top side as well as in the inner layers of the printed circuit board, and these further reduce the available copper cross section.

At the same time, there are thermal and mechanical demands, for example with regard to vibrations that occur, which require a minimum number of fastening points of the printed circuit board to the heat sink. Specifically in the case of high-current and high-voltage applications, this leads to a reduction in the maximum possible power density of the printed circuit board.

A further problem which occurs in the case of screwing processes is the development of electrically conductive wear during the screwing process, that, as FOD particles, may lead to short circuits.

There is a need to provide a printed circuit board assembly that may obviate one or more of the drawbacks or limitations in the related art.

### SUMMARY

The present disclosure is based on the object of providing a printed circuit board assembly that manages with a small number of screw connections or even without screw connections and nevertheless achieves effective thermal contact between printed circuit board-based power electronics assemblies and a heat sink.

The scope of the present disclosure is defined solely by the appended claims and is not affected to any degree by the statements within this summary.

In a first aspect, a printed circuit board assembly is provided. The printed circuit board assembly comprises a printed circuit board having a top side and an underside, electrical modules having a top side and an underside, a heat sink, which is thermally coupled with the underside of the electrical modules, and a hold-down device. The heat sink has a structured top side that includes a plurality of cavities and bearing structures arranged between the cavities and forming a bearing surface for the printed circuit board. The underside of the printed circuit board lies on the bearing surface, the region of the underside that is lying on the bearing surface forms a bottom abutment surface. The electrical modules project into the cavities of the heat sink, and that projecting structures of the hold-down device lie against the top side of the printed circuit board at contact points located opposite the bottom abutment surface and apply a hold-down force to the contact points.

The solution is based on the idea of replacing conventional screw connections for connecting a printed circuit board to a heat sink by an assembly in that a contact pressure of the printed circuit board against the heat sink is provided by projecting structures such as pins or webs on the underside of a hold-down device or of a cover, the printed circuit board is arranged between such projecting structures and a bearing surface of the heat sink and, without play and without interrupting the force flow, transmits and introduces the hold-down force introduced at its top side via the projecting structures further and into the heat sink at its bottom side. The printed circuit board is, as it were, clamped between the projecting structures of the hold-down device or of the cover, on the one hand, and the bearing surface at the top side of the heat sink.

The solution makes it possible to reduce conventional screw connections or even avoid them altogether, so that the power density of the printed circuit board increases as a result of an increase in the copper cross section of the current-carrying inner layers of the printed circuit board.

A further advantage includes that a more compact construction is possible by avoiding insulation paths between metal screws and copper layers that were necessary hitherto.

The printed circuit board layout is also simplified as a result of the solution, since screw connections and the metal threads in the printed circuit board that are necessary therefor are no longer required, or at least there is a reduced number of screw connections.

It should be noted that, the expression “contact point” is to be understood as being not a mathematical point but a small area or a locally limited region. The expression “contact point” indicates that the force that is introduced is introduced in a locally limited region of the printed circuit board. This locally limited region may be configured, for example, in the form of a circle or rectangle or in another way.

The side of the printed circuit board that faces the heat sink is referred to as the underside of the printed circuit board, irrespective of the actual orientation of the printed circuit board in space.

In some embodiments, the printed circuit board assembly includes a hold-down device having the projecting structures on its underside, the hold-down device is arranged on the top side of the printed circuit board and the projecting structures of the hold-down device lie against the contact points of the top side. A hold-down device may serve to press the printed circuit board in the direction towards the heat sink so that the electrical modules arranged on the underside of the printed circuit board may come into intensive thermal contact with the heat sink and thus undergo improved cooling. The hold-down device used has structures on its underside that project such that the printed circuit board is arranged between the bearing surface on the top side of the heat sink and the projecting structures of the hold-down device, so that a direct force flow from the projecting structures via the printed circuit board into the heat sink may take place.

In some embodiments, the hold-down device has greater mechanical rigidity than the printed circuit board. It is thus provided that a contact force of the printed circuit board and thus of the electrical modules arranged on the underside of the printed circuit board against the heat sink is effected via the hold-down device.

In some embodiments, the hold-down device may in principle have any shape and configuration, for example may be planar or formed by ribs. In order to provide sufficient mechanical rigidity, the hold-down device has elements elements that have the form of a T-beam or double-T-beam. T-Beams and double-T-beams are known to have high flexural rigidity. The mentioned elements are, for example, ribs formed by the hold-down device.

In some embodiments, the hold-down device lies in its edge region on the heat sink. To this end, the heat sink has structures that allow the hold-down device to lie thereon. For example, the hold-down device lies on the heat sink all round.

In some embodiments, the hold-down device is screwed to the heat sink only in its edge region so as to provide that the hold-down device, and thus the printed circuit board, is securely fastened to the heat sink. Since screw connections are formed only in the edge region of the hold-down device, the printed circuit board arranged between the hold-down device and the heat sink is unaffected by the screw connections or is affected likewise only in its edge region.

In some embodiments, the printed circuit board assembly has a cover that presses the hold-down device against the heat sink in its edge region. In this case, the frictional contact between the hold-down device and the heat sink is provided via the cover, without the need for screw connections.

In some embodiments, the cover has projecting structures, such as, for example, pins or webs, which lie against points on the top side of the hold-down device that are arranged opposite the projecting structures on the underside of the hold-down device. The cover is thus configured also to exert a pressure on the hold-down device from above. The hold-down force provided by the projecting structures of the hold-down device may thus be provided or even enhanced. The hold-down device is also prevented from curving upwards, that would reduce the hold-down force.

In some embodiments, the hold-down device includes a metallic material. For example, it is a metallic metal having a high modulus of elasticity, such as, for example, aluminum, steel, spring steel and titanium. If the hold-down device includes an electrically conductive material, the hold-down device is at least partially coated or overmolded with an electrically non-conductive material for the purposes of electrical insulation. In the case of aluminum, an eloxal process, for example, may be used for electrical insulation.

In some embodiments, the printed circuit board assembly is configured without a hold-down device but includes a cover that has the projecting structures, the cover is arranged on the top side of the printed circuit board and the projecting structures of the cover lie against the contact points of the top side. In this configuration, the cover assumes the function described hitherto of the hold-down device. The projecting structures, which generate a hold-down force, are formed directly on the cover. The printed circuit board assembly is accessible from above. For example, it is provided in this configuration that further printed circuit boards located above are not arranged above the circuit board in question (so-called printed circuit board stacks). If this is the case, the printed circuit board stacks would have to be opened in the region of the cover.

In some embodiments, the required contact pressure of the printed circuit board (and thus of the electrical modules arranged on the underside of the printed circuit board) against the heat sink may be provided.

In some embodiments, the projecting structures of a hold-down device or of a cover have an oversize in the sense that, in the assembled state of the printed circuit board assembly, the projecting structures exert a contact pressure on the top side of the printed circuit board. The length of the projecting structures is thus such that they do not merely lie without play on the surface of the printed circuit board but, as it were, press into the surface of the printed circuit board to a certain extent and in so doing provide a contact pressure.

In some embodiments, the projecting structures of a hold-down device or of a cover are of resilient form. For example, springs may be provided for this purpose, the springs being guided in sleeves formed in the projecting structures.

In some embodiments, a resilient configuration is also formed in the region of the bearing surface on the top side of the heat sink. To this end, for example, that resilient elements are formed in the region of the bearing surfaces of the heat sink.

In some embodiments, a heat-conducting material is arranged in the cavities of the heat sink between the underside of the electrical modules and the top side of the heat sink. The thermal coupling of the electrical modules with the heat sink is thus improved. Also, heat-conducting materials are used to compensate for height tolerances. This is because, where there are multiple electrical modules to be cooled, there may be gaps with different gap sizes relative to the heat sink, and these are compensated for in order to provide effective cooling.

Paste systems, for example, are used as heat-conducting materials, and these are applied to the cooling surface and compensate for minimal gaps and roughness. If higher gap dimensions need to be compensated for, thermally conductive foils or so-called gap pads or gap filler materials up to a few millimeters thick are used. Such heat-conducting materials are also referred to as thermal interface material (TIM).

In some embodiments, the contact points of the top side of the printed circuit board, against that points projecting structures lie, and/or the abutment surface of the underside of the printed circuit board, which lies on the bearing surface of the structured top side of the heat sink, are/is mechanically reinforced. Mechanical reinforcement is not provided over the entire surface of the printed circuit board but only in the region of the contact points at that the projecting structures come into contact.

In some embodiments, the nature of the mechanical reinforcement may be varied. The mechanical reinforcement is formed by at least one top metal pad and/or at least one bottom metal pad.

In some embodiments, the mechanical reinforcement is formed by at least two metal pads, the metal pads are additionally connected by metallic vias. By the provision of vias that are likewise metallized and connect the at least two metal pads, the assembly is mechanically stiffened. The metal pads are, for example, copper pads.

In some embodiments, the contact points on the top side of the printed circuit board are circular in form.

In some embodiments, the structures of the hold-down device or of the cover that press against the contact points are circular pins. For example, it may be provided as an alternative that the contact points are of rectangular form, the hold-down device or cover has webs that press against the contact points.

In some embodiments, the bearing structures of the structured top side of the heat sink are formed by webs, which is to say elongate structures of quadrangular form. The webs delimit the cavities that accommodate the electrical modules arranged on the underside of the printed circuit board.

### BRIEF DESCRIPTION OF THE DRAWINGS

The printed circuit board assembly of the present disclosure explained in greater detail below by a plurality of example embodiments and with reference to the figures, in which:

FIG. 1 shows an example of a printed circuit board assembly having a printed circuit board that lies on a heat sink, where pins or webs of a hold-down device lie against the top side of the printed circuit board at contact points and apply a hold-down force to the contact points, and where the contact points are arranged opposite an abutment surface on the underside of the printed circuit board, at that the printed circuit board lies on bearing structures of the heat sink;

FIG. 2 shows an example of contact points and abutment surfaces of a printed circuit board of FIG. 1 that are mechanically reinforced by metal pads;

FIG. 3 shows an example of a printed circuit board assembly of FIG. 1, where pins of the hold-down device and/or bearing structures of the heat sink are of resilient form;

FIG. 4 shows an example of a printed circuit board assembly of FIG. 1, where the printed circuit board assembly includes cover that likewise has pins or webs that lie against points on the top side of the hold-down device that are arranged opposite the pins or webs on the underside of the hold-down device;

FIG. 5 shows an example of a printed circuit board that lies on a heat sink, where pins or webs of a cover lie against the top side of the printed circuit board at contact points and apply a hold-down force to the contact points, and where the contact points are arranged opposite an abutment surface on the underside of the printed circuit board, at that the printed circuit board rests on bearing structures of the heat sink;

FIG. 6 shows an example of a hold-down device; and

FIG. 7 shows an example of a top view of the top side of a printed circuit board, where there are shown contact points at that pins of a hold-down device or of a cover according to the printed circuit board assemblies of FIGS. 1 and 3 to 5 come into contact and introduce a hold-down force, and where screw connections according to the prior art are additionally shown.

### DETAILED DESCRIPTION

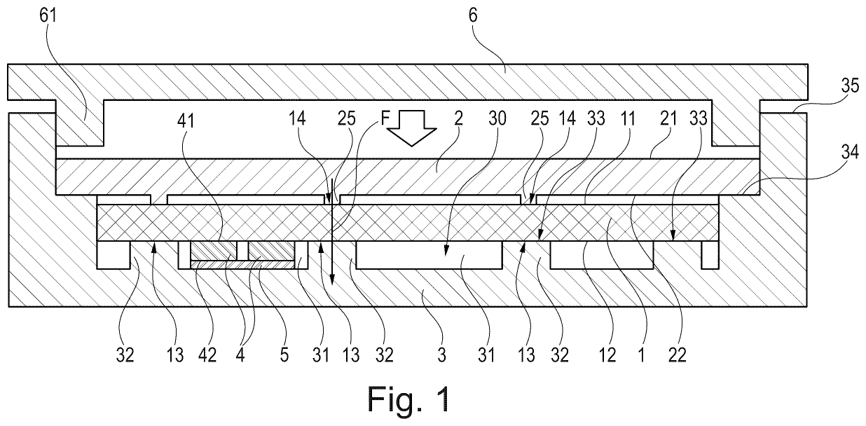

FIG. 1 shows a printed circuit board assembly includes a printed circuit board 1, electrical modules 4, a heat sink 3, a hold-down device 2 and a cover 6.

The printed circuit board 1 may include a multiplicity of circuit board layers (not shown separately), that are arranged one above the other. In this case, a topmost printed circuit board layer forms a top side 11 of the printed circuit board 1 and a bottommost printed circuit board layer forms an underside 12 of the printed circuit board 1.

On the underside 12 of the printed circuit board 1 there are arranged the electrical modules 4, that each have a top side 41 and an underside 42. The electrical modules 4 are connected to the printed circuit board 1 by surface-mounting, where electrical contact faces (solder pads) on the underside 12 of the printed circuit board 1 are connected via soldered connections to electrical contact faces on the top side 41 of the electrical modules 4. The electrical modules 4 are active components, for example components or assemblies of the power electronics, which require cooling by the heat sink 3.

The heat sink 3 has a structured top side 30 facing the printed circuit board 1. The structuring of the top side 30 is such that a plurality of cavities or recesses 31 are formed on the top side 30. Between the cavities 31 are bearing structures in the form of projecting webs 32. The top side of the webs 32 forms a bearing surface 33 for the printed circuit board 1. The regions of the underside of the printed circuit board that lie on the bearing surface 33 form a bottom abutment surface 13 of the printed circuit board.

The electrical modules 4 project into the cavities 31. The printed circuit board 1 covers the cavities 31 on the top side. An optional heat-conducting material 5, that thermally couples the underside 42 of the electrical modules 4 to the heat sink 3 and is also referred to as a thermal interface material (TIM), is arranged on a bottom surface of the heat sink 3 in the cavity 31, between the modules 4 to be cooled and the heat sink 3. This material is, for example, a heat-conducting mat or a heat-conducting paste. By the heat-conducting material 5, a gap between the module 4 and the heat sink 3 is avoided.

It should be noted that only two of the electrical modules 4 are shown in FIG. 1. In actual fact, electrical modules are located in each cavity 31 in a corresponding manner. It may be provided that the electrical modules are each arranged one behind the other in rows (perpendicular to the plane of the image of FIG. 1).

The cavities 31 separated from one another by the webs 32 may be configured in a multiplicity of geometrical arrangements. For example, it may be provided that the cavities 31 form multiple parallel rows, which are separated from one another by the webs 32. In other exemplary embodiments, it may be provided that the cavities are rectangular or square and are surrounded by webs 32 on all four sides.

Above the printed circuit board 1 there is arranged the hold-down device 2. The hold-down device 2 has a top side 21 and an underside 22 facing the printed circuit board 1. On the underside 22 of the hold-down device 2 there are arranged a plurality of projecting structures in the form of pins or webs 25. “Pins” refers to structures that project in the direction towards the printed circuit board 1 and are at least approximately punctiform, for example circular. “Webs” refers to structures that project in the direction towards the printed circuit board 1 and have an elongate extent. The webs are, for example, elongate structures of quadrangular form. In principle, the projecting structures may also have a different form, for example a corrugated form. In the following description, no distinction is made between pins and webs since they may both form the structure 25 in the cross-sectional view in question.

The pins or webs 25 of the hold-down device lie against the top side 11 of the printed circuit board at contact points 14. The pins or webs 25 are configured such that they exert a pressure on the top side 11 of the printed circuit board 1 at the contact points 14, where the end faces of the pins or webs 25 come into abutment at the contact points 14. Via the contact points 14, the pins or webs 25 introduce a hold-down force into the printed circuit board 1. The contact points 14 are located opposite the bottom abutment surfaces 13. This makes it possible for a force flow (represented by way of example by the arrow F) to take place from the hold-down device 2, namely the pins or webs 25 of the hold-down device 2, via the printed circuit board 1 into the bearing structures 32 of the heat sink 3 and the heat sink 3. The hold-down force provided in this way at multiple contact points 14 on the top side 11 of the printed circuit board 1 provides that the printed circuit board 1, and thus the electrical modules 4 arranged on the underside 12 of the printed circuit board 1, come into thermal contact with the heat sink 3 and are correspondingly efficiently cooled. This is achieved by the special structure with the projecting structures 25, the contact points 14 on the top side 11 of the printed circuit board 1, the opposite abutment surfaces 13 on the underside 12 of the printed circuit board 1, and the bearing structures 32 of the heat sink 3, without the need for a screw connection.

The hold-down device 2 lies in its edge region on a bearing surface 34 of the heat sink 3. In order to secure the vertical position of the hold-down device 2, a cover 6 is provided and lies on a surface 35 of the heat sink 3. The cover 6 includes projecting webs 61 or a projecting encircling edge 61 that, when the cover 6 is fastened to the heat sink 3, press/presses the edge of the hold-down device 2 against the heat sink 3 and in so doing secures it in its vertical position.

It may additionally be provided that the hold-down device 2 is screwed to the heat sink in its edge region (in the region of the bearing surface 34). It may further be provided that the cover is screwed to the heat sink in the region of the bearing surface 35. However, such screwing does not affect the printed circuit board 1.

The hold-down device 2 may have greater mechanical rigidity than the printed circuit board 1, so that an efficient introduction of force into the printed circuit board 1 via the projecting structures 25 is possible. It may be provided that the hold-down device includes a metallic material such as, for example, aluminum, steel, spring steel or titanium. It may further be provided that the hold-down device 2 is coated or overmolded with a non-conductive material for the purposes of electrical insulation.

It may further be provided that the pins or webs 25 have a slight oversize and thus, in the assembled state, do not merely lie against the top side 11 of the printed circuit board 1 but, owing to their oversize, introduce a force into the contact points 14.

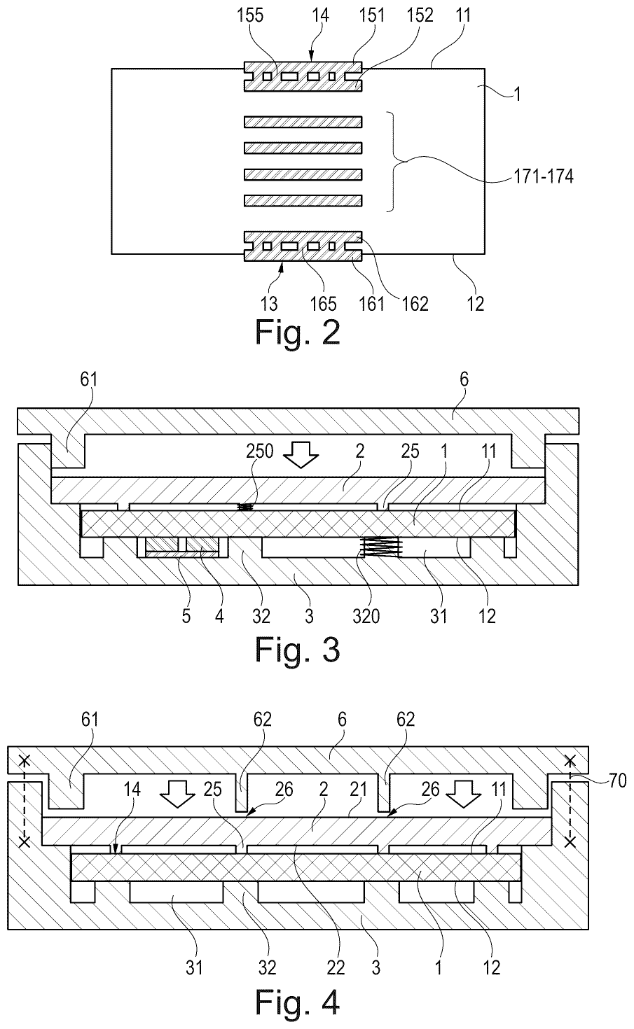

For an effective introduction of the hold-down force introduced into the contact points 14, it is advantageous for the contact points 14 on the top side 11 of the printed circuit board 1 and the abutment surfaces 13 on the underside 12 of the printed circuit board 1, that lie on the bearing surface 33 of the webs 32, to be mechanically reinforced. An exemplary embodiment in this regard is illustrated in FIG. 2.

FIG. 2 shows a printed circuit board 1 having a top side 11 and an underside 12. A contact point 14 is shown on the top side 11 according to FIG. 1. An abutment surface 13 is shown on the underside 12 according to FIG. 1. The top contact point 14 is formed by two copper pads 151, 152, that are connected by vias 155 in order to increase the rigidity and enhance the mechanical stability. In a corresponding manner, the bottom abutment surface is formed by two copper pads 161, 162, that are connected together by vias 165. FIG. 2 furthermore shows a plurality of current-carrying copper layers 171-174, between which there are insulated layers, as is known to a person skilled in the art. The copper pads 151, 152, 161, 162 connected together by vias in each case form a layer structure, which enhances the mechanical stability.

It should be noted that the copper pads 151, 152, 161, 162 with the vias 155, 165 do not serve to carry current. The corresponding layers are not current-carrying layers and are not electrically connected to the other layers 171-174 of the circuit. The copper pads 151, 152, 161, 162 may have the form of circular or rectangular pads of limited size.

FIG. 3 shows a modification of the exemplary embodiment of FIG. 1, that differs from the exemplary embodiment of FIG. 1 in that the projecting structures on the underside of the hold-down device 2 and/or the bearing structures 32 of the cavity 3 are in each case of resilient form. Thus, it is shown, by way of example and schematically, that the projecting structures 25 on the underside of the hold-down device 2 have resilient elements 250. For example, pins 25 include springs 250, that are guided in a sleeve. It is likewise shown, by way of example and schematically, that the bearing structure 32 on the top side of the heat sink 3 has resilient elements 320. For example, the webs 32 include springs 320, that are guided in a sleeve. The resilient configuration serves to provide a contact pressure.

FIG. 4 shows a further modification of the exemplary embodiment of FIG. 1, that differs from the exemplary embodiment of FIG. 1 in that the cover 6 also has on its inner side projecting structures in the form of pins or webs 62. The pins or webs 62 of the cover 6 are positioned such that they lie against points 26 on the top side 21 of the hold-down device 2 that are opposite the pins or webs 25 on the underside 22 of the hold-down device 2. The pins or webs 62 prevent the hold-down device 2 from being able to curve upwards, in that case the hold-down force acting at the contact points 14 would be reduced. By positioning the pins or webs 62 of the cover 6 and the pins or webs 25 of the hold-down device 2 on opposite sides of the hold-down device 2, an effective introduction of force into the contact points 14 is provided.

It may be provided that the cover 6 is screwed in its edge region to the heat sink 3 via screw connections 70 shown schematically, so that the hold-down device 2 is secured in the vertical direction.

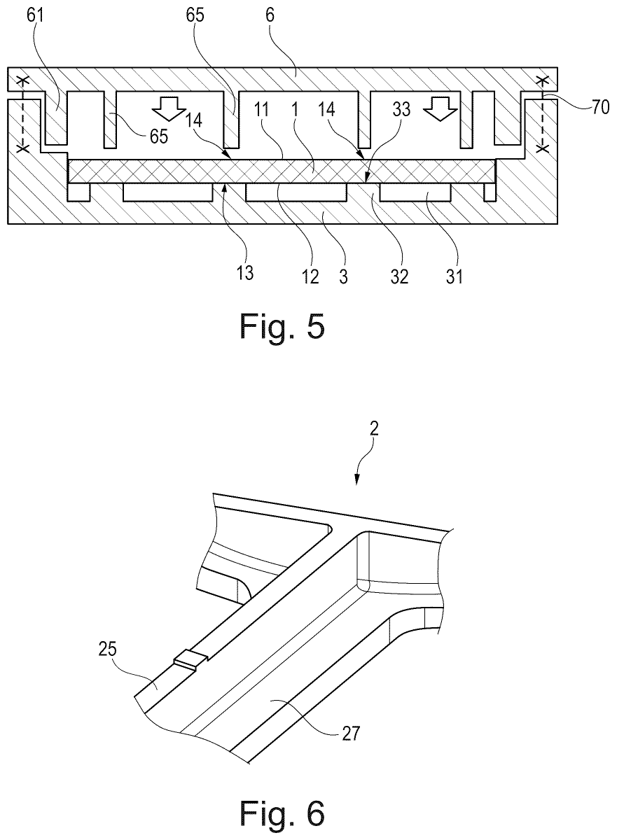

FIG. 5 shows a further modification of the exemplary embodiment of FIG. 1, where a hold-down device is not present in the exemplary embodiment of FIG. 5.

The function of the hold-down device is here assumed by the cover 6. The cover 6 has on its underside projecting structures in the form of pins or webs 65, that lie against the top side of the hold-down device 2 and apply a hold-down force to the contact points 14 of the hold-down device 2.

It may be provided that the cover 6 is screwed in its edge region to the heat sink 3 via screw connections 70 shown schematically, so that a continuous introduction of force into the printed circuit board 1 via the contact points 14 is provided.

It should be noted that the electrical modules 4 in FIGS. 4 and 5 are not shown separately but as described in relation to FIG. 1, are arranged on the underside of the printed circuit board 1 and project into the cavities 31.

FIG. 6 shows, by way of example, an exemplary embodiment of a hold-down device 2, that is shown only in portions. The hold-down device includes rib-shaped elements 27 in the form of a T-beam, in order to achieve high rigidity. Webs 25 corresponding to the webs 25 of FIGS. 1, 3 and 4 project. FIG. 6 makes it clear that the hold-down device 2 may in principle be provided in a large number of configurations. It may include individual ribs, according to FIG. 6, that have the form, for example, of a T-beam or double-T-beam. However, it may also be planar, for example in the form of a plate, from that the projecting structures 25 protrude.

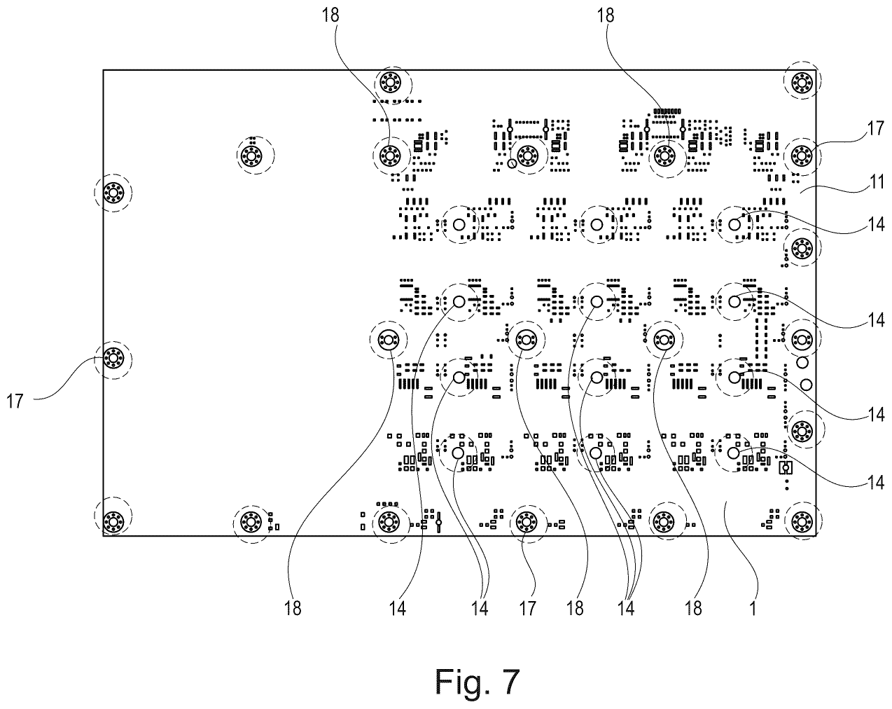

FIG. 7 shows a top view of the top side 11 of a printed circuit board 1. The representation serves to illustrate the advantages associated with the present disclosure.

Thus, the representation includes conventional metal threads 17, 18, that receive metal screws and serve to provide screw connections. The metal threads 17 are located at the edge of the printed circuit board 1, and the metal threads 18 are located in the inside of the printed circuit board. The metal threads 17, 18 effect an interruption and reduction of the copper cross section of the individual copper layers of the printed circuit board.

FIG. 7 furthermore shows contact points 14 at which, in a printed circuit board assembly according to the disclosure according to FIGS. 1-5, webs or pins or other projecting structures of a hold-down device or of a cover come into abutment. The pressure points 14 are circular and are accordingly subjected to a force by pins of a hold-down device or of a cover.

The contact points 14 replace the metal threads 17, 18, where the copper cross section of the current-carrying inner layers of the printed circuit board 1 is increased.

Alternatively, only the internal metal threads 18 are replaced by the contact points 14, where the external metal threads 17 remain to additionally secure the printed circuit board 1 by lateral screw connections. This does not significantly affect the current path within the printed circuit board 1 but merely increases the necessary surface area of the printed circuit board 1 slightly.

The disclosure is not limited to the embodiments described above and different modifications and improvements may be made without deviating from the concepts described here. It is furthermore pointed out that any of the features described may be used separately or in combination with any other features, provided that they are not mutually exclusive. The disclosure extends to and includes all combinations and sub-combinations of one or more features that are described here. If ranges are defined, these ranges therefore include all the values within these ranges as well as all the partial ranges that lie within a range.

1. A printed circuit board assembly comprising:
a printed circuit board having a top side and an underside;
electrical modules having a top side and an underside, wherein the top side of the electrical modules are arranged on the underside of the printed circuit board;
a heat sink that is thermally coupled with the underside of the electrical modules; and
a hold-down device,
wherein the heat sink has a structured top side comprising cavities and bearing structures arranged between the cavities and forming a bearing surface for the printed circuit board,
wherein the underside of the printed circuit board lies on the bearing surface,
wherein the region of the underside that is lying on the bearing surface forms a bottom abutment surface,
wherein the electrical modules project into the cavities of the heat sink, and
wherein the hold-down device has projecting structures that lie against the top side of the printed circuit board at contact points located opposite the bottom abutment surface and apply a hold-down force to the contact points.

2. The printed circuit board assembly of claim 1, wherein the projecting structures are on an underside of the hold-down device, and
wherein the hold-down device is arranged on the top side of the printed circuit board and the projecting structures lie against the contact points of the top side.

3. The printed circuit board assembly of claim 1, wherein the hold-down device has a mechanical rigidity that is greater than a mechanical rigidity of the printed circuit board.

4. The printed circuit board assembly of claim 3, wherein the hold-down device comprises elements that have a form of a T-beam or double-T-beam.

5. The printed circuit board assembly of claim 1, wherein an edge region of the hold-down device lies on the heat sink.

6. The printed circuit board assembly of claim 1, wherein the hold-down device is screwed to the heat sink only in an edge region of the hold-down device.

7. The printed circuit board assembly of claim 1, wherein the hold-down device comprises a metallic material.

8. The printed circuit board assembly of claim 1, further comprising:
a cover that presses the hold-down device against an edge region of the heat sink.

9. The printed circuit board assembly of claim 8, wherein the cover has projecting structures that lie against points on the top side of the hold-down device that are arranged opposite projecting structures on the underside of the hold-down device.

10. The printed circuit board assembly of claim 8, wherein the cover has projecting structures,
wherein the cover is arranged on the top side of the printed circuit board, and
wherein the projecting structures of the cover lie against the contact points of the top side of the printed circuit board.

11. The printed circuit board assembly of claim 1, wherein the projecting structures have an oversize such that the projecting structures exert a contact pressure on the top side of the printed circuit board in the assembled state of the printed circuit board assembly.

12. The printed circuit board assembly of claim 1, wherein the projecting structures are of a resilient form.

13. The printed circuit board assembly of claim 1, wherein resilient elements are formed in the region of the bearing surfaces of the heat sink.

14. The printed circuit board assembly of claim 1, wherein a heat-conducting material is arranged in the cavities of the heat sink between the underside of the electrical modules and the top side of the heat sink.

15. The printed circuit board assembly of claim 1, wherein the contact points of the top side of the printed circuit board, which lie against points of the projecting structures, are mechanically reenforced, and/or
wherein the abutment surface of the underside of the printed circuit board, which lies on the bearing surface of the structured top side of the heat sink, is mechanically reinforced.

16. The printed circuit board assembly of claim 15, wherein a respective mechanical reinforcement of the contact points and/or abutment surface is formed by at least one top metal pad and at least one bottom metal pad.

17. The printed circuit board assembly of claim 16, wherein the respective mechanical reinforcement is formed by at least two metal pads, and
wherein the at least two metal pads are connected by metallic vias.

18. The printed circuit board assembly of claim 1, wherein the projecting structures are formed by pins or webs.

19. The printed circuit board assembly of claim 1, wherein the pressure points on the top side of the printed circuit board are circular in form.

20. The printed circuit board assembly of claim 1, wherein the bearing structures of the structured top side of the heat sink are formed by webs.
